(19) United States
(12) Patent Application Publication
(10) Pub. No.: US 2022/0037603 A1
(43) Pub. Date: Feb. 3, 2022

(54) RADIATIVE HEAT-BLOCKING MATERIALS

(71) Applicant: King Abdullah University of Science and Technology, Thuwal (SA)

(72) Inventors: Derya BARAN, Thuwal (SA); Nicola GASPARINI, Thuwal (SA); Joel Robert TROUGHTON, Thuwal (SA); Daniel Thomas James BRYANT, Thuwal (SA)

(21) Appl. No.: 17/299,962

(22) PCT Filed: Dec. 3, 2019
(86) PCT No.: PCT/IB2019/060413

§ 371 Date: Jun. 4, 2021

Related U.S. Application Data
(60) Provisional application No. 62/775,040, filed on Dec. 4, 2018.
(60) Provisional application No. 62/781,051, filed on Dec. 18, 2018.

(51) Int. Cl. H01L 51/42; H01L 27/30; H01L 51/00

(52) U.S. Cl. CPC H01L 51/4253; H01L 51/0036; H01L 27/302

(57) ABSTRACT

Embodiments include radiative heat-blocking materials comprising one or more non-fullerene components and optionally one or more hole-scavenging components. Embodiments further include windows comprising a transparent photovoltaic device configured to transmit visible light and absorb infrared radiation, wherein an active layer of the photovoltaic device comprises the radiative heat-blocking material. Embodiments further include other devices based on the radiative heat-blocking materials.

### BACKGROUND

The solar electromagnetic radiation that reaches the Earth's surface largely includes radiation in the ultraviolet, visible, and infrared regions of the electromagnetic spectrum. For a material to be visibly transparent to human eyes, it generally should not absorb light in the ‘visible’ region of the electromagnetic spectrum (between about 400-700 nm). In addition, the sun's spectral output is such that there is more energy to be harvested in the infrared regions compared to the ultraviolet region, with near-infrared and infrared radiation being responsible for much of the radiative heating experienced by objects exposed to direct sunlight.

Conventional heat-blocking windows rely on films coated on glass in an attempt to block as much of the near-infrared portion of the spectrum (780-2500 nm) as possible. The two most commonly used methods commercially are based on pyrolytically coated glass (fluorine-doped tin oxide, FTO, coated) or use alternating thin layers of silver and insulator. These are referred to, industrially, as Low-E and Solar control glass and are widely manufactured and deployed commercially. However, the spectral irradiance transmitted through such conventional heat-blocking films can still be improved to provide greater reductions in heat transmission into enclosed spaces of, for example, buildings and other types of dwellings. In addition, none of the conventional films have been integrated into photovoltaic devices to achieve heat-blocking and generate electricity, while also allowing visible light to pass through. While some other photovoltaic devices based on organic materials (as well more conventional photovoltaics based on silicon, CdTe and others) may absorb infrared radiation, they fail to exhibit or maintain high visible transparency. Other conventional photovoltaics absorb light in this visible region, thus making them unsuitable for windows due to an unacceptable reduction in transparency.

Accordingly, it would be desirable to provide a material that is capable of transmitting visible light to provide transparency, while also absorbing infrared radiation to reduce heat transmission and optionally generate electricity if incorporated into a photovoltaic device.

### SUMMARY

In general, embodiments of the present disclosure describe radiative heat-blocking materials, devices based on the radiative heat-blocking materials, and the like.

Embodiments of the present disclosure describe a radiative heat-blocking material comprising one or more non-fullerene components and one or more hole-scavenging components, wherein the heat-blocking material transmits visible light and absorbs infrared radiation.

Embodiments of the present disclosure further describe a heat-blocking window comprising a radiative heat-blocking material deposited on a window and configured to transmit substantially visible light and absorb substantially infrared radiation, wherein radiative heat-blocking material includes one or more non-fullerene components and optionally one or more hole-scavenging components.

Embodiments of the present disclosure is a heat-blocking window comprising a photovoltaic device fabricated on a window, wherein the photovoltaic device includes a radiative heat-blocking material as an active layer, wherein the radiative heat-blocking material comprises one or more non-fullerene components and optionally one or more hole-scavenging components, wherein the heat-blocking active material is configured to transmit substantially visible light and absorb substantially infrared radiation, wherein the absorbed infrared radiation is used by the photovoltaic device to generate electricity. In an embodiment of the present disclosure, the photovoltaic device comprises a first electrode material, a radiative heat-blocking material as an active layer, and a second electrode material. In an embodiment of the present disclosure, the photovoltaic device comprises a substrate, a first electrode material, a first selective contact layer, a radiative heat-blocking material as an active layer, a second selective contact layer, and a second electrode material.

Embodiments of the present disclosure describe methods of preparing radiative heat-blocking materials comprising contacting one or more non-fullerene components and optionally one or more hole-scavenging components in a presence of a solvent sufficient to form a blended solution; and depositing the blended solution on a support.

Embodiments of the present disclosure describe methods of fabricating a photovoltaic device comprising depositing a blended solution (e.g., a radiative heat-blocking material) on a first material sufficient to form an active layer, wherein the blended solution includes one or more non-fullerene components and optionally one or more hole-scavenging components; and depositing a second material on the active layer, wherein the first material and the second material are on opposing sides of the active layer.

Embodiments of the present disclosure describe methods of using a photovoltaic device comprising irradiating a surface of a photovoltaic device comprising a radiative heat-blocking material, wherein the radiative heat-blocking material comprises one or more non-fullerene components and optionally one or more hole-scavenging components; and converting light to electricity or electricity to light.

The details of one or more examples are set forth in the description below. Other features, objects, and advantages will be apparent from the description and from the claims.

### BRIEF DESCRIPTION OF DRAWINGS

This written disclosure describes illustrative embodiments that are non-limiting and non-exhaustive. In the drawings, which are not necessarily drawn to scale, like numerals describe substantially similar components throughout the several views. Like numerals having different letter suffixes represent different instances of substantially similar components. The drawings illustrate generally, by way of example, but not by way of limitation, various embodiments discussed in the present document.

Reference is made to illustrative embodiments that are depicted in the figures, in which:

FIG. 1 is a flowchart of a method of a method of fabricating an active layer of an optoelectronic device, according to one or more embodiments of the present disclosure.

FIG. 2 is a schematic diagram of an optoelectronic device, according to one or more embodiments of the present disclosure.

FIG. 3 is a schematic diagram of an optoelectronic device showing various optional layers of an optoelectronic device, according to one or more embodiments of the present disclosure.

FIG. 4 is a flowchart of a method of fabricating an optoelectronic device, according to one or more embodiments of the present disclosure.

FIG. 5 is a flowchart of a method of using an optoelectronic device comprising an active layer of the present disclosure, according to one or more embodiments of the present disclosure.

FIG. 6 is a graphical view of the transmission of light through the individual layers and their comparison with the device full stack in the ultraviolet (UV)-to-near-infrared spectrum, according to one or more embodiments of the present disclosure.

FIG. 7 is a graphical view showing a comparison of the transmission of the device full stack with commercially available Low-E glass with comparable average visible transparency or transmittance (AVT) in the UV-near-infrared spectrum, according to one or more embodiments of the present disclosure.

FIG. 8 is a graphical view showing spectral irradiance against wavelength for the American Society for Testing and Materials (ASTM) G173-03 Air Mass 1.5 (or “AM1.5”) reference spectra [NREL], where AM0 represents the solar spectrum present above the earth's atmosphere, AM1.5 Global represents the solar spectrum present at sea-level with the sun directly overhead, AM1.5 Direct considers AM1.5 Global in addition to the light emanating from a disc 2.5 degrees around the sun, which is the focus herein, according to one or more embodiments of the present disclosure.

FIG. 9 is a graphical view showing spectral irradiance of AM1.5G after attenuation through commercially available Low-E glass and the “device full stack” in the near-infrared portion of the spectrum, where reduced transmission equates to a greater degree of heat blocking, according to one or more embodiments of the present disclosure.

FIG. 10 is a graphical view showing absorption intensity of the diluted organic active layer over time while being subjected to continuous temperature stress (80 degrees centigrade) over the course of 523 hours, where a drop in peak absorption of 2.4% occurs over this time-frame, according to one or more embodiments of the present disclosure.

FIG. 11 is a schematic diagram showing a configuration of an inverted organic solar cell, according to one or more embodiments of the present disclosure.

FIG. 12 is a schematic diagram of a chemical formula for donor/acceptor materials used as a photoactive layer, according to one or more embodiments of the present disclosure.

FIG. 13 is a graphical view showing current density-voltage (J-V) characteristics of a single component photoactive layer comprising a non-fullerene component, according to one or more embodiments of the present disclosure.

FIG. 14 is a graphical view of a diluted system comprising a ratio of the hole-scavenging component to non-fullerene component of 1:10, according to one or more embodiments of the present disclosure.

FIG. 15 is a graphical view of UV-Visible (Vis) plots of diluted PTB7-th:IEICO-4F blend in comparison with human eye sensitivity for AVT, where PTB7-Th is poly([2,6′-4,8-di(5-ethylhexylthienyl)benzo[1,2-b;3,3-b]dithiophene]{3-fluoro-2[(2-ethylhexyl)carbonyl]thieno[3,4-b]thiophenediyl}) and IEICO-4F is 2,2′-((2Z,2′Z)-(((4,4,9,9-tetrakis(4-hexylphenyl)-4,9-dihydro-s-indaceno[1,2-b:5,6-b′]dithiophene-2,7-diyl)bis(4-((2-ethylhexyl)oxy)thiophene-5,2-diyl))bis(methanylylidene))bis(5,6-difluoro-3-oxo-2,3-dihydro-1H-indene-2,1-diylidene))dimalononitrile (IEICO-4F), according to one or more embodiments of the present disclosure.

FIG. 16 is a graphical view of UV-Vis plots of diluted PTB7-th:IEICO-4F blend in comparison with human eye sensitivity for transparency, according to one or more embodiments of the present disclosure.

FIG. 17 is an optical micrographs of a solar module with three interconnected sub-cells, where the insets on the left represent optical magnifications of the interconnection region, where the laser lines P1, P2, and P3 are highlighted, and where the photo-inactive area (dead area, blue) and total area (yellow) of the module are highlighted as well, according to one or more embodiments of the present disclosure.

FIG. 18 is a graphical view of normalized power conversion efficiency (PCE) of 1:2 and 1:10 D/A based solar cells in the course of light exposure, according to one or more embodiments of the present disclosure.

FIGS. 19A-19B are graphical views showing (A) current-voltage characteristics of binary and ternary devices at 1 sun illumination; and (B) normalized PCE as a function of time for binary and ternary devices degraded at 80 degrees C. in inert conditions, according to one or more embodiments of the present disclosure.

FIG. 20 is a graphical view showing current-voltage response and statistics for single- and multi-junction solar cells based on the diluted organic system, according to one or more embodiments of the present disclosure.

FIG. 21 is a schematic drawing of a tandem solar cell, according to one or more embodiments of the present disclosure.

### DETAILED DESCRIPTION

The present disclosure relates to radiative heat-blocking materials, devices based on the radiative heat-blocking materials, and the like. The radiative heat-blocking materials can be used to prevent or otherwise reduce radiation heat transfer in which thermal energy is transferred in the form of electromagnetic waves through a medium. For example, the radiative heat-blocking materials can absorb light in the infrared region (e.g., near-infrared region) of the electromagnetic spectrum to prevent infrared radiation from passing through the material and heating other objects. The radiative heat-blocking materials can absorb the infrared light, while also transmitting light in the visible region of the electromagnetic spectrum. The radiative heat-blocking materials thus can block radiation heat transfer, while also maintaining high visual transparency.

The radiative heat-blocking materials can also be prepared with photoactive materials and integrated into photovoltaic devices. By integrating, as active layers, the heat-blocking materials in this way, photovoltaic devices can be fabricated that not only absorb infrared radiation and transmit visible light, but that also harvest the infrared radiation absorbed by the heat-blocking materials to generate electricity. Unlike conventional materials and devices, the photovoltaic devices into which the heat-blocking materials are integrated can maintain high visible transparency, while also achieving high power conversion efficiencies and significant reductions in heat transmission through the devices. These photovoltaic devices provide opportunities for new applications. For example, they can be fabricated on windows such that the sun's near-infrared radiation is not allowed to merely pass through and heat an enclosed space (e.g., in a building). Rather it is absorbed and used to generate electricity, while allowing natural visible light to illuminate the space.

### Definitions

The terms recited below have been defined as described below. All other terms and phrases in this disclosure shall be construed according to their ordinary meaning as understood by one of skill in the art.

As used herein, the term “non-fullerene component” generally refers to any material other than fullerenes, which are commonly used in conventional materials.

As used herein, the term “hole-scavenging component” generally refers to any material that promotes the extraction of charges from, for example, the non-fullerene component.

As used herein, “visible light” refers to electromagnetic radiation with any wavelength or frequency in the visible region of the electromagnetic spectrum. The boundary between and within the regions of the electromagnetic spectrum (e.g., radio waves, microwaves, infrared, visible, ultraviolet, X-rays, gamma rays, etc.) are not precisely defined by, for example, a universally agreed-upon standard. Accordingly, any recognized, accepted, or reasonable range of wavelengths or frequencies known in the art can be used to characterize or describe “visible light.” For example, “visible light” can be characterized by a wavelength ranging from about 380 nm to about 700 nm, or any value or incremental range between about 380 nm and about 700 nm.

As used herein, “infrared radiation” refers to electromagnetic radiation with wavelengths or frequencies in the infrared region of the electromagnetic spectrum. The boundary between and within the regions of the electromagnetic spectrum (e.g., radio waves, microwaves, infrared, visible, ultraviolet, X-rays, gamma rays, etc.) are generally not universally agreed-upon and can vary depending on, for example, the standard used. Accordingly, any recognized, accepted, or reasonable range of wavelengths or frequencies known in the art can be used to characterize or describe “infrared radiation.” For example, “infrared radiation” can be characterized by a wavelength ranging from about 700 nm to about 3000 nm, or any value or incremental range between about 700 nm and about 3000 nm Infrared radiation can also be divided into smaller regions within the infrared region. The term “infrared radiation” thus can include, but is not limited to, regions known in the art as near-infrared, short-wavelength infrared, mid-wavelength infrared, long-wavelength infrared, far-infrared, or combinations thereof

As used herein, the term “ratio” includes molar ratio, mass ratio, volume ratio, and any other ratios known in the art for describing quantities of materials.

As used herein, “contacting” refers to the act of touching, making contact, or of bringing to immediate or close proximity, including at the cellular or molecular level, for example, to bring about a physiological reaction, a chemical reaction, or a physical change, e.g., in a solution, in a reaction mixture, in vitro, or in vivo. Accordingly, adding, stirring, treating, tumbling, vibrating, shaking, mixing, and applying are forms of contacting to bring two or more components together.

As used herein, “depositing” refers to disposing, printing (e.g., ink-jet printing), doctor blade coating, bar coating, slot-die coating, spray coating, growing, etching, doping, epitaxy, thermal oxidation, sputtering, casting, depositing (e.g., chemical vapor deposition, physical vapor deposition, etc.), spin-coating, evaporating, applying, treating, and any other technique and/or method known to a person skilled in the art.

As used herein, “irradiating” refers to exposing to radiation. The radiation may comprise any wavelength, frequency, or range thereof on an electromagnetic spectrum. For example, irradiating may refer to exposing to a near-infrared radiation.

As used herein, “converting” refers to any process for converting energy.

### Radiative Heat-Blocking Materials

Embodiments of the present disclosure describe radiative heat-blocking materials that can be applied as heat-blocking coatings or films on substrates, integrated into photovoltaic devices as an active layer, and the like. In general, the radiative heat-blocking materials absorb infrared radiation that can be harvested to generate electricity, while also transmitting visible light, thereby maintaining high visual transparency. In certain embodiments, infrared radiation, such as near-infrared, can be the region of the electromagnetic spectrum that is targeted and absorbed for at least two reasons. First, infrared radiation is responsible for much of the radiative heating of objects exposed to sunlight. Accordingly, blocking heat in the form of infrared radiation can result in significant reductions in heat transmission. Second, most of the solar electromagnetic radiation that reaches the Earth's surface is infrared radiation. For example, the sun's spectral output can be apportioned as follows: about 52 to 55 percent infrared (most of which is near-infrared at the Earth's surface), about 42 to 43 percent visible, and about 3 to 5 percent ultraviolet. Accordingly, more energy can be harvested from infrared radiation, or near-infrared, than can be harvested from ultraviolet or visible. The infrared region is thus absorbed and the visible region is transmitted through the material. In other embodiments, wavelengths of light other than visible light and infrared radiation can be transmitted and absorbed, respectively.

The radiative heat-blocking material can comprise one or more non-fullerene components and optionally one or more hole-scavenging components. The non-fullerene component can be a transparent ambipolar material that is capable of transmitting visible light and/or generating electron holes/free charges in the absence of a donor material. The one or more non-fullerene components are adequate alone, without any hole-scavenging component, and thus can be used as such. In some instances, it may be desirable to combine the one or more non-fullerene components with one or more hole-scavenging components to, for example, enhance power conversion efficiency (PCE). In these instances, the hole-scavenging component can be added to act as a “hole scavenger” that promotes the extraction of charges from the non-fullerene component and improves various photovoltaic parameters (e.g., fill factor (FF), short-circuit current density (J_{SC}), PCE, etc.). Since the hole-scavenging component can, in some instances, diminish the transparency of the radiative heat-blocking material (e.g., by absorbing at least some visible light) when combined with the non-fullerene component, the hole-scavenging component can be added in a low amount relative to the non-fullerene component so that the radiative heat-blocking material and/or photovoltaic device maintains high visual transparency.

In one or more embodiments of the present disclosure, the heat-blocking layers can be provided as single-component systems, or as diluted organic systems in which one or more non-fullerene components are combined with one or more hole-scavenging components. In one embodiment, a single-component system is provided, wherein the heat-blocking material comprises a non-fullerene component, without a hole-scavenging component. In another embodiment, a binary diluted system is provided, wherein the radiative heat-blocking material comprises a non-fullerene component and a hole-scavenging component. In yet another embodiment, a tertiary diluted system is provided, wherein the radiative heat-blocking material comprises a non-fullerene component, a first hole-scavenging component, and a second hole-scavenging component, wherein the first hole-scavenging component and second hole-scavenging component are different. In yet another embodiment, the radiative heat-blocking material comprises a first non-fullerene component, a second non-fullerene component different from the first non-fullerene component, and a hole-scavenging component. These are provided as examples and shall not be limiting. Higher order systems can be used herein without departing from the scope of the present disclosure.

Where the one or more non-fullerene components are combined with one or more hole-scavenging components to form diluted organic systems—such as, binary diluted systems and tertiary diluted systems—the ratio of the one or more hole-scavenging components to one or more non-fullerene components can be adjusted to maintain transparency, as well as to tune PCE of a photovoltaic device. In some embodiments, the ratio of the one or more hole-scavenging components to one or more non-fullerene components can range from about 0:1 to about 1:25. For example, the ratio of the one or more hole-scavenging components to the one or more non-fullerene components can be about 0:1, about 1:1, about 1:2, about 1:3, about 1:4, about 1:5, about 1:6, about 1:7, about 1:8, about 1:9, about 1:10, about 1:11, about 1:12, about 1:13, about 1:14, about 1:15, about 1:16, about 1:17, about 1:18, about 1:19, about 1:20, about 1:21, about 1:22, about 1:23, about 1:24, about 1:25, greater than about 1:25, or any increment thereof. In one embodiment, the ratio of the one or more hole-scavenging components to one or more non-fullerene components can range from about 0:1 to about 1:5.

The non-fullerene components can be selected from small molecules, oligomers, polymers, cross-linked metastructures, and combinations thereof. Examples of suitable non-fullerene components include, but are not limited to, one or more of rhodanine-benzothiadiazole-coupled indacenodithiophene (IDTBR); indacenodithieno[3,2-b]thiophene, IT), end-capped with 2-(3-oxo-2,3-dihydroinden-1-ylidene)malononitrile (INCN) groups (ITIC); indaceno[1,2-b:5,6-b′]dithiophene and 2-(3-oxo-2,3-dihydroinden-1-ylidene)malononitrile (IEIC); 2,2′-((2Z,2′Z)-((5,5′-(4,4,9,9-tetrakis(4-hexylphenyl)-4,9-dihydro-s-indaceno[1,2-b:5,6-b′]dithiophene-2,7-diyl)bis(4-((2-ethylhexyl)-oxy)thiophene-5,2-diyl))bis(methanylylidene))bis(3-oxo-2,3-di-hydro-1H-indene-2,1-diylidene))dimalononitrile (IEICO); naphthalene diimide (NDI); bay-linked perylene bisimide (di-PBI); perylene bisimide (PBI); Benzotriazole-Containing End-Capped with Thiazolidine-2,4-dione (TD); Naphthalocyanine (NC); Phthalocyanine (PC); Naphtho[1,2-c:5,6-c′]bis[1,2,5]thiadiazole; (2E,2′E)-3,3′-(2,5-dimethoxy-1,4-phenylene)bis(2-(5-(4-(N-(2-ethylhexyl)-1,8-naphthalimide)yl)thiophen-2-yl)acrylonitrile) (NIDCS-MO); thieno[3,4-b] thiophene and 2-(1,1-dicyanomethylene)rhodanine combination (ATT-1); (3,9-bis(4-(1,1-dicyanomethylene)-3-methylene-2-oxo-cyclopenta[b]thiophen)-5,5,11,11-tetrakis(4-hexylphenyl)-dithieno[2,3-d′: 2,3-d′]-s-indaceno[1,2-b: 5,6-b′]-dithiophene (ITCC); Indanedione; Dicyannovinyl; Benzothiadiazole; Diketopyrolopyrrole; arylene diimide; and IDIC.

The hole-scavenging component can also be selected from small molecules, oligomers, polymers, cross-linked metastructures, and combinations thereof. Examples of suitable hole-scavenging components include, but are not limited to, one or more of thiophene, acene, fluorine, carbazole, indacenodithieno thiophene, indacenothieno thiphene, benzodithiazole, thieny-benzodithiophene-dione, benzotriazole, and diketopyrrolopyrrole.

The one or more non-fullerene components and the one or more hole-scavenging components may be blended or mixed to form a radiative heat-blocking material. A thickness of the radiative heat-blocking material can be on a length scale ranging from nanometers to centimeters. For example, in an embodiment, a thickness of the radiative heat-blocking material can range from about 1 nm to about 10 cm. In an embodiment, a thickness of the radiative heat-blocking material can range from about 1 nm to about 500 μm. In an embodiment, a thickness of the radiative heat-blocking material can range from about 1 nm to about 1000 nm In other embodiments, a thickness of the active layer may be less than about 1 nm. Depositing or coating the radiative heat-blocking material can be achieved via a variety of manufacturing techniques (e.g., large scale manufacturing techniques). The manufacturing techniques may include one or more of vacuum deposition, roll-to-roll, sheet-to-sheet, slot-die coating, blade coating, gravure printing, spray coating, spin coating, drop casting, flexographic printing, and bar coating. In many embodiments, the deposition and/or coating technique may be used to achieve a desired thickness of the radiative heat-blocking material.

In embodiments, the radiative heat-blocking materials (or photovoltaic devices) have an average visible transparency (AVT) of at least about 30%. For example, in certain embodiments, the radiative heat-blocking materials can have ab AVT of about 30% or greater, about 35% or greater, about 40% or greater, about 45% or greater, about 50% or greater, about 55% or greater, about 60% or greater, about 65% or greater, about 70% or greater, about 75% or greater, about 80% or greater, about 85% or greater, or about 90% or greater. In embodiments, the radiative heat-blocking materials have an AVT in the range of about 25% to about 100%, or any value or incremental range between about 25% and about 100%.

### Methods of Preparing Radiative Heat-Blocking Materials

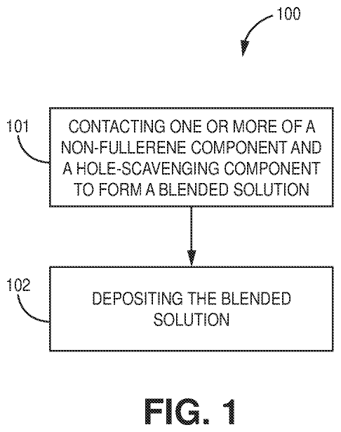

FIG. 1 is a flowchart of a method 100 of preparing a radiative heat-blocking materials, according to one or more embodiments of the present disclosure. As shown in FIG. 1, the method 100 comprises contacting 101 one or more non-fullerene components and optionally one or more hole-scavenging components in a presence of a solvent sufficient to form a blended solution; and optionally depositing 102 the blended solution on a support.

At step 101, one or more non-fullerene components and optionally one or more hole-scavenging components can be contacted in a presence of a solvent sufficient to form a blended solution. The contacting can proceed by bringing the one or more non-fullerene components, optional hole-scavenging components, and solvent into physical contact, or at least immediate or close proximity. The contacting can be performed by mixing, blending, stirring, adding, and dissolving, among other techniques. For example, in one embodiment, a non-fullerene component is contacted with a solvent to form a solution. In another embodiment, a non-fullerene component and a hole-scavenging component are contacted in a solvent to form a blended solution. In another embodiment, a non-fullerene component, a first hole-scavenging component, and a second hole-scavenging component different from the first hole-scavenging component are contacted in a solvent to form a blended solution. In another embodiment, a first non-fullerene component, a second non-fullerene component different from the first non-fullerene component, and a hole-scavenging component are contacted in a solvent to form a blended solution.

The one or more non-fullerene components and/or one or more hole-scavenging components may include any of non-fullerene components and hole-scavenging components described herein. The amount of the one or more hole-scavenging components and/or the one or more non-fullerene components contacted in the presence of a solvent can be defined by a ratio of the one or more hole-scavenging components to the one or more non-fullerene components. The ratio of the one or more hole-scavenging components to the one or more non-fullerene components can range from about 0:1 to about 1:25. For example, the ratio can be about 0:1, about 1:1, about 1:2, about 1:3, about 1:4, about 1:5, about 1:6, about 1:7, about 1:8, about 1:9, about 1:10, about 1:11, about 1:12, about 1:13, about 1:14, about 1:15, about 1:16, about 1:17, about 1:18, about 1:19, about 1:20, about 1:21, about 1:22, about 1:23, about 1:24, about 1:25, greater than about 1:25, or any increment thereof. In one embodiment, the ratio of the one or more hole scavenging components to the one or more non-fullerene components ranges from about 1:5 to about 0:1.

The solvent can include any solvent suitable for dissolving or blending the one or more non-fullerene components and one or more optional hole-scavenging components. For example, the solvent can include one or more of organic solvents, inorganic solvents, aqueous solvents, polar solvents, and non-polar solvents. In an embodiment, the solvent is an organic solvent. In an embodiment, the solvent is one or more of xylene, tetralin, mesitylene, chloroform, chlorobenzene, and dichlorobenzene. At least one benefit of the present disclosure is that the solvent can be an environmentally friendly solvent or a green chemistry solvent. An example of such solvents includes, but is not limited to, one or more of xylene, tetralin, and mesitylene.

At step 102, the blended solution can optionally be deposited on a support. Depositing can include, but is not limited to, one or more of coating, casting, and depositing. For example, depositing can include one or more of printing, doctor-blade coating, spin-coating, blade-coating, spray coating, bar-coating, slot-die coating, knife-coating, roll-coating, wire-bar coating, and dip-coating. In one embodiment, depositing includes spin-coating. For example, a speed (e.g., revolutions per minute (rpm)) of a spin-coating device can be adjusted to obtain different thicknesses of the blended solution and thus of the radiative heat-blocking material. For example, the blended solution can be deposited at speeds ranging from about 100 rpm to about 5000 μm. In another embodiment, the blended solution is deposited at speeds ranging from about 300 rpm to about 2000 rpm. In yet another embodiment, depositing can include scalable processes, such as blade-coating. A thickness of the blended solution and/or radiative heat-blocking material can be on a length scale ranging from nanometers to centimeters.

The blended solution can be deposited onto a transparent or substantially transparent support. The supports are not particularly limited and the particular support onto which the blended solution is deposited can depend on the application. For example, the supports can be selected from substrates and layers of a photovoltaic device. In some embodiments, the blended solution can be deposited on substrates selected from transparent or substantially transparent substrates, such as, PET, polycarbonates, and quartz, among other materials. In other embodiments, the depositing step may be performed one or more times sufficient to form all or at least some of the layers of the photovoltaic device. In an embodiment, the transparent substrate is a glass window. In an embodiment, the layer of the photovoltaic device is an electrode material (e.g., first electrode material and/or second electrode material). In an embodiment, the layer of the photovoltaic device is a selective contact layer (e.g., first selective contact layer and/or second selective contact layer). In an embodiment, the layer of the photovoltaic device is a substrate layer, which can be a coated or uncoated substrate layer. For example, in an embodiment, the substrate layer is glass coated with indium tin oxide. In an embodiment, the substrate layer is glass coated with fluorine-doped tin oxide. Other examples are provided elsewhere herein and also known in the art.

In an embodiment, the method may comprise preparing a blended solution, wherein the blended solution includes one or more non-fullerene components and one or more hole-scavenging components dissolved in an organic solvent (e.g., an environmentally friendly or green chemistry solvent). In an embodiment, the method may comprise washing a substrate. For example, the substrate may be washed with one or more of detergent water, deionized water, acetone, and isopropyl alcohol. In an embodiment, the washing may include washing in an ultrasonic bath for a specified period of time. In an embodiment, the method may comprise preparing a precursor solution of a first or second selective layer. In an embodiment, the method may comprise treating the substrate. For example, the substrate may be subjected to UV-ozone treatment. In an embodiment, the precursor solution of the first or second selective layer may be spin coated onto the substrate and/or a composite comprising the substrate and the first and/or second selective layer. In an embodiment, the method comprises heating the deposited precursor solution. In an embodiment, the method comprises spin-coating the blended solution on any layer of the optoelectronic device. In an embodiment, the method may comprise depositing a layer via thermal evaporation.

### Radiative Heat-Blocking Materials as Active Layers of Photovoltaic Devices

Embodiments of the present disclosure describe photovoltaic devices comprising radiative heat-blocking materials as active layers. Any of the radiative heat-blocking materials of the present disclosure can be used herein. For example, the one or more non-fullerene components and optional hole-scavenging component(s) can be added to or combined to obtain a bulk heterojunction of a photovoltaic device that affords both heat-blocking and electricity-generating benefits. In particular, the active layer can exhibit the benefits of radiative heat blocking by absorbing infrared radiation (e.g., near-infrared) to prevent it from passing through the photovoltaic device and heating another environment or object, while allowing visible light to pass freely through the layer and the device. The photovoltaic device can then harvest the infrared radiation absorbed by the active layer and use it to generate electricity, while maintaining high power conversion efficiencies. In other embodiments, the active layer can absorb electromagnetic radiation of a first wavelength or wavelength range and transmit electromagnetic radiation of a second wavelength or wavelength range.

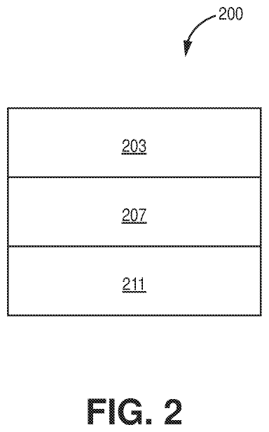

FIG. 2 is a schematic diagram of a photovoltaic device 200, according to one or more embodiments of the present disclosure. As shown in FIG. 2, the photovoltaic device 200 comprises a first electrode material 203, a radiative heat-blocking material as an active layer 207, and a second electrode material 211. The active layer 207 can be disposed between the first electrode material 203 and the second electrode material 211. For example, in an embodiment, the active layer 207 can be in contact with a surface of the first electrode material 203 and a surface of the second electrode material 211, wherein the first electrode material 203 and the second electrode material 211 are on opposing sides of the active layer 207. In some embodiments, the photovoltaic device 200 can optionally further comprise one or more of a substrate 201 (not shown), a first selective contact layer 205 (not shown), and a second selective contact layer 209 (not shown). In addition or in the alternative, in some embodiments, an interdigitated electrode(s) (not shown) is used.

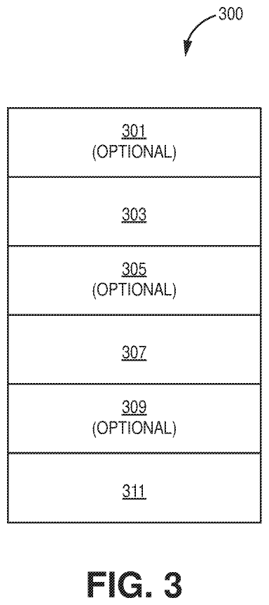

FIG. 3 is a schematic diagram of a photovoltaic device 300, according to one or more embodiments of the present disclosure. As shown in FIG. 3, the photovoltaic device 300 can comprise a substrate 301, a first electrode material 303, a first selective contact layer 305, a radiative heat-blocking material as an active layer 307, a second selective contact layer 309, and a second electrode material 311. Each of the substrate 301, first selective layer 305, and second selective layer 309 is optional and thus can be excluded from the photovoltaic device 300. The active layer 307 is typically disposed between the first electrode material 303 and the second electrode material 311. In an embodiment, the first selective contact layer 305 is positioned between and in contact with the first electrode material 303 and the active layer 307. In an embodiment, the second selective contact layer 309 is positioned between and in contact with the second electrode material 311 and the active layer 307. In an embodiment, the substrate 301 is in contact with the first selective contact layer 305 or the second selective contact 309 layer, and otherwise exposed to an environment. In an embodiment, the photovoltaic device can be configured as substrate/first electrode material/first selective contact layer/active layer/second selective contact layer/second electrode material. In addition or in the alternative, in some embodiments, an interdigitated electrode (not shown) can be used.

The radiative heat-blocking material, or active layer 307, can include any of the radiative heat-blocking materials of the present disclosure. For example, the radiative heat-blocking material can be transparent or substantially transparent and/or transmit visible light and absorb infrared radiation. The radiative heat-blocking materials can comprise one or more non-fullerene components and optionally one or more hole-scavenging components as described in more detail elsewhere in the present disclosure.

The electrode materials can comprise one or more of a first electrode material 303 and a second electrode material 311. The first electrode material 303 and/or the second electrode material 311 can be transparent or substantially transparent. In an embodiment, at least one of the first electrode material 303 and the second electrode material 311 is transparent or substantially transparent. In an embodiment, the first electrode material 303 and the second electrode material 311 are transparent or substantially transparent. In embodiments in which the first electrode material 303 and the second electrode material 311 (and optionally the other layers) are transparent and combined with the active layers 307 of the present disclosure, the entire photovoltaic device can exhibit high transparency in a range visible to the human eye (i.e., a “transparent” photovoltaic device).

In an embodiment, either the first electrode material 303 or the second electrode material 311 can be a high work function conductive electrode and the other electrode material can be a low work function conductive electrode. For example, a cathode can comprise a high work function metal or metal oxide and/or an anode can comprise a low work function metal. In these embodiments, the photovoltaic device (e.g., an organic solar cell) can be characterized as comprising an inverted configuration. In other embodiments, the photovoltaic device can be characterized as comprising a non-inverted configuration (e.g., a conventional or normal configuration). Accordingly, the first electrode material 303 and the second electrode material 311 can be selected based on an architecture of the photovoltaic device (e.g., based on inverted configurations and non-inverted configurations).

The first electrode material 303 and/or the second electrode material 311 can each be independently selected from a doped oxide, metallic conductor, conducting polymer, carbon-based conductor, and combinations thereof.

The doped oxide can include any material with high concentrations of free electrons. For example, the doped oxide can be selected from a metal oxide semiconductor and conductor. In an embodiment, the doped oxide can be selected from indium-doped tin oxide (ITO), fluoride-doped tin oxide (FTO), aluminum-doped zinc oxide (AZO), and In₂O₃.

The metallic conductor can include any metals with complementary work functions with respect to the HOMO/LUMO of the charge selective layers, allowing, for example, favorable electron or hole transfer between layers. The metallic conductor can be one or more of a solid, grid, and wire-mesh array. In many embodiments, the metallic conductor includes one or more of silver, gold, aluminum, copper, titanium, zinc, steel, and chromium.

The conducting polymer can include any material with high conductivity and/or transparency. For example, the conducting polymer can include PEDOT:PSS.

The carbon-based conductor can include one or more of graphene, carbon black, graphite, carbon nanotubes, and carbon nanowires. For example, in some embodiments, the carbon-based conductor includes one or more of a single-wall carbon nanotube, a single-wall carbon nanowire, multi-wall carbon nanotube, and multi-wall carbon nanowire, where the carbon single-wall or multi-wall nanotube or nanowire structures are sufficiently narrow in one dimension so as to allow for high optical transparency while maintaining high electrical conductivity. Typical concentrations of carbon nanotubes and nanowires in an ink range between about 0.001% and about 1%, but typically can be about 0.1% by weight. In the case of graphene, graphene oxide, and graphite, the number of carbon atom layers should be low enough to allow for high optical transparency while maintaining high electrical conductivity. Layer thicknesses typically range between about 1 and about 10 atoms thick, preferably about 1. The dimensions of these carbon sheets ranges between about 5 μm and about 10,000 μm, typically about 50 μm. In the case of graphite and carbon black, a sufficiently small addition of these material can be used in conjunction with a high optical transparency electrical conductor to further improve conductivity without imparting a high degree of opacity.

The substrate 301 can include any suitable substrate. In some embodiments, suitable substrates can include substrates with a high degree of flatness on a micron-scale or smaller. In some embodiments, suitable substrates can include transparent substrates, while, in other embodiments, suitable substrates can be selected from non-transparent, partially transparent, and substantially transparent. In many embodiments, the optional substrate 301 can be selected from glass, metallic, polymer, and ceramic. The glass substrate can be provided as any type of glass, including, for example, one or more of soda-lime glass, borosilicate glass, fused silica glass, and aluminosilicate glass. The metallic substrate can include one or more of titanium, nickel, iron, zinc, and copper. The polymer substrate can include one or more of PET, PEN, PU, PC, PMMA, PETG, silicone, polyetherimide (PEI), nylon/PA, PE, and PP. The ceramic substrate can include one or more of aluminum oxide, silicon dioxide, quartz, slate, kaolinite, montmorillonite-smectite, illite, chlorite, and calcium aluminate.

The first selective contact layer 305 and/or second selective contact layer 309 can include one or more of a p-type selective contact layer and n-type selective contact layer. The first selective contact layer 305 and/or second selective contact layer 309 can be transparent or substantially transparent. In embodiments in which the photovoltaic device is provided as a non-inverted photovoltaic device, the first selective contact layer 305 is a p-type selective contact layer and the second selective contact layer 309 is a n-type selective contact layer. In embodiments in which the photovoltaic device is provided as an inverted photovoltaic device, the first selective contact layer 305 is a n-type selective contact layer and the second selective contact layer 309 is a p-type selective contact layer. The p-type selective contact layer can include one or more of PEDOT:PSS, nickel oxide, graphene, fluorine-doped CsSnI₃, perovskites, metal-phthalocynanine (e.g., copper-phthalocyanine), Cul, PFN, metal-thiocyanate, and derivatives thereof. The n-type selective layer can include one or more of phthalocyanine, polyacetylene, poly(phenylene vinylene), and derivatives thereof. In addition or in the alternative, the first selective layer and/or second selective layer can include bathocuproine and/or metal oxide semiconductors. The metal oxide semiconductors can include one or more of TiO₂, ZnO, SnO₂, Nb₂O₅, SrTiO₃, NiO, WO₃, V₂O₅, indium tin oxide, fluorine-doped tin oxide, and mixtures thereof.

In some embodiments, the photovoltaic device 300 can be provided as a multi-junction or tandem solar cell in which another solar cell is used as, or at least provided on, the substrate 301 of the photovoltaic device 300. The photovoltaic device 300 can thus be “stacked” on the solar cell 301 to form a tandem solar cell. In an embodiment, the solar cell 301, positioned as the front cell, can absorb some visible light, while also allowing infrared radiation to pass freely through the cell and at least enough visible light to maintain transparency or at least some transparency. The infrared radiation can thus be allowed to reach and be absorbed by the photovoltaic device 300, which is positioned as the back cell. Other configurations are possible and thus the examples provided herein shall not be limiting.

In an embodiment, the photovoltaic device 300 is provided as a tandem solar cell. For example, the photovoltaic device 300 can comprise a solar cell as a substrate 301, a first electrode material 303; a first selective contact layer 305; an active layer 307; a second selective contact layer 309; and a second electrode material 311. The solar cell 301 can comprise glass, an electrode material, and a layer of amorphous silicon (a-Si), wherein the layer of amorphous silicon comprises positively doped a-Si:H, undoped a-Si:H, and negatively doped a-Si:H. The electrode material and the first electrode material can be provided on opposing sides of the layer of amorphous silicon. The glass can be provided such that it is in contact with the electrode material and otherwise exposed to the environment. The first electrode material 303, first selective contact layer 305, active layer 307, second selective contact layer 309, and second electrode material 311 can be provided as described elsewhere herein.

In an embodiment, the photovoltaic device 300 is provided as an inverted photovoltaic device. The inverted photovoltaic device can comprise a substrate 301, a first electrode material 303, a first selective contact layer 305, an active layer 307, a second selective contact layer 309, and a second electrode material 311. In embodiments in which the photovoltaic device is inverted, the first selective contact layer 305 is n-type and the second selective contact layer 309 is p-type.

In an embodiment, the photovoltaic device 300 is a non-inverted photovoltaic device. The non-inverted photovoltaic device can comprise a substrate 301, a first electrode material 303, a first selective contact layer 305, an active layer 307, a second selective contact layer 309, and a second electrode material 311. In embodiments in which the photovoltaic device is non-inverted, the first selective contact layer 305 is p-type and the second selective contact layer 309 is n-type.

In embodiments, the photovoltaic devices, including any layer of the photovoltaic device, have an AVT in the range of about 25% to about 100%, or any value or incremental range between about 25% and about 100%. In embodiments, the photovoltaic device has a PCE in the range of about 1% to about 50%, or any value or incremental range between about 1% and about 50%. In embodiments, the photovoltaic devices, including any layer of the photovoltaic device, transmits light having a first wavelength and absorbs light having a second wavelength, wherein the first wavelength and second wavelength are selected from any single wavelength or range of wavelengths of the electromagnetic spectrum (e.g., including, but not limited to, visible light and infrared radiation).

### Heat-Blocking Windows Using Radiative Heat-Blocking Materials

Embodiments of the present disclosure describe a heat-blocking substrate comprising a radiative heat-blocking material deposited as a layer, film, or coating on a substrate and configured to transmit visible light and absorb infrared radiation, wherein the radiative heat-blocking material comprises one or more non-fullerene components and one or more hole-scavenging components. Any of the radiative heat-blocking materials of the present disclosure can be used herein. The substrate is not particularly limited, but is typically a transparent or substantially transparent substrate, such as a glass window. For example, the radiative heat-blocking materials can be deposited on glass windows of dwellings, buildings, and other structures to absorb infrared or near-infrared radiation and thus achieve significant reductions in heat transmission into enclosed or interior spaces thereof, while also transmitting visible light such that the spaces can be illuminated. In an embodiment, the visible light includes electromagnetic radiation with wavelengths ranging from about 380 nm to about 700 nm In an embodiment, the infrared radiation includes electromagnetic radiation with wavelengths ranging from about 700 nm to about 3000 nm.

In another aspect of the present invention, a photovoltaic device comprising a radiative heat-blocking active layer can be fabricated on a transparent substrate, such as a window, to prevent or otherwise reduce the amount of solar energy that is allowed to pass into an environment (e.g., an enclosed space of a building or dwelling) through the material and/or substrate. By absorbing infrared light in this way, the photovoltaic device can achieve significant reductions in heat transmission, while also harvesting the infrared radiation absorbed by the heat-blocking material and using it to generate electricity. By transmitting light in the visible region of the electromagnetic spectrum, the photovoltaic device provides nearly unrestricted access to natural or artificial light by allowing it to pass freely through the device.

Embodiments of the present disclosure thus describe a heat-blocking window comprising a photovoltaic device fabricated on a window, wherein the photovoltaic device includes a radiative heat-blocking material as an active layer. In an embodiment, the photovoltaic device is transparent or substantially transparent. In an embodiment, the window is a glass window. In an embodiment, the radiative heat-blocking material comprises one or more non-fullerene components and optionally one or more hole-scavenging components. In an embodiment, the heat-blocking material is configured to transmit substantially visible light and absorb substantially infrared radiation. In an embodiment, the absorbed infrared radiation is used by the photovoltaic device to generate electricity. In an embodiment, the visible light includes electromagnetic radiation with wavelengths ranging from about 380 nm to about 700 nm In an embodiment, the infrared radiation includes electromagnetic radiation with wavelengths ranging from about 700 nm to about 3000 nm.

In an embodiment, the photovoltaic device further comprises a first electrode material and a second electrode material disposed on opposing sides of the radiative heat-blocking material. In an embodiment, a first selective contact layer is disposed between the radiative heat-blocking material and the first electrode material. In an embodiment, a second selective contact layer is disposed between the radiative heat-blocking material and the second electrode material. In an embodiment, a substrate is in contact with either the first electrode material or the second electrode material and otherwise exposed to the environment.

### Methods of Fabricating Photovoltaic Devices Based on Radiative Heat-Blocking Materials

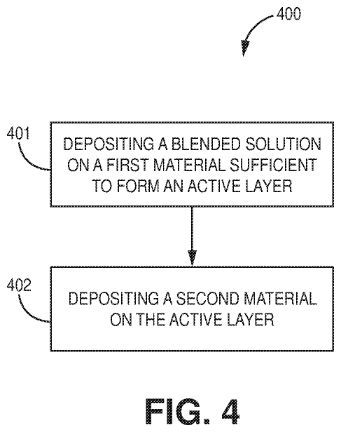

FIG. 4 is a flowchart of a method of fabricating a photovoltaic device, according to one or more embodiments of the present disclosure. As shown in FIG. 4, the method 400 comprises depositing 401 a blended solution (e.g., a radiative heat-blocking material) on a first material sufficient to form an active layer, wherein the blended solution includes one or more non-fullerene components and optionally one or more hole-scavenging components; and depositing 402 a second material on the active layer, wherein the first material and the second material are on opposing sides of the active layer.

Depositing can include, among other things, one or more of printing, spin-coating, blade-coating, and spray-coating. In many embodiments, depositing includes spin-coating. Any of the non-fullerene components and hole-scavenging components of the present disclosure may be used here. In an embodiment, the blended solution is a radiative heat-blocking material. In an embodiment, the radiative heat-blocking material comprises one or more non-fullerene components, without a hole-scavenging component. In an embodiment, the radiative heat-blocking material comprises a non-fullerene component and a hole-scavenging component. In an embodiment, the radiative heat-blocking material comprises a non-fullerene component, a first hole-scavenging component, and a second hole-scavenging component different from the first hole-scavenging component. In an embodiment, the radiative heat-blocking material comprises a first non-fullerene component, a second non-fullerene component different from the first non-fullerene component, and a hole-scavenging component.

The first material and the second material can include any layers or components of a photovoltaic device. In an embodiment, the first material refers to one or more of a substrate, a first electrode material, and a first selective contact layer. In an embodiment, the first material refers to one or more of a second electrode material and a second selective contact layer. In an embodiment, the second material refers to one or more of a substrate, a first electrode material, and a first selective contact layer. In an embodiment, the second material refers to a second electrode material and a second selective contact layer. In an embodiment, the method comprises depositing a first precursor solution, wherein the first precursor solution forms a first selective contact layer. In an embodiment, the method comprises depositing a second precursor solution, wherein the second precursor solution forms a second selective contact layer.

In an embodiment, the method can comprise preparing a blended solution, wherein the blended solution includes one or more non-fullerene components and one or more hole-scavenging components dissolved in an organic solvent (e.g., an environmentally friendly or green chemistry solvent). In an embodiment, the method can comprise washing a substrate. For example, the substrate can be washed with one or more of detergent water, deionized water, acetone, and isopropyl alcohol. In an embodiment, the washing can include washing in an ultrasonic bath for a specified period of time. In an embodiment, the method can comprise preparing a precursor solution of a first or second selective layer. In an embodiment, the method can comprise treating the substrate. For example, the substrate can be subjected to UV-ozone treatment. In an embodiment, the precursor solution of the first or second selective layer can be spin coated onto the substrate and/or a composite comprising the substrate and the first or second selective layer. In an embodiment, the method comprises heating the deposited precursor solution. In an embodiment, the method comprises spin-coating the blended solution on any layer of the optoelectronic device. In an embodiment, the method may comprise depositing a layer via thermal evaporation.

### Methods of Using Photovoltaic Devices Based on Radiative Heat-Blocking Materials

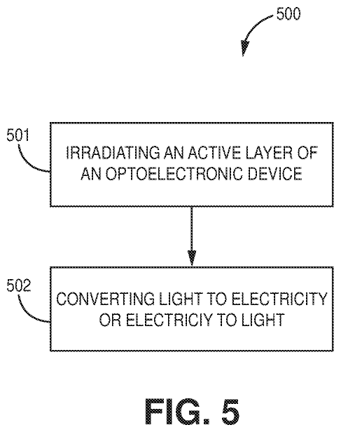

FIG. 5 is a flowchart of a method 500 of using a photovoltaic device, according to one or more embodiments of the present disclosure. As shown in FIG. 5, the method 500 comprises irradiating 501 a surface of a photovoltaic device comprising a radiative heat-blocking material, wherein the radiative heat-blocking material comprises one or more non-fullerene components and optionally one or more hole-scavenging components; and converting 502 light to electricity or electricity to light. In many embodiments, the radiative heat-blocking material is provided as an active layer or photoactive layer.

Irradiating generally refers to exposing to radiation. The radiation can comprise any wavelength, frequency, or range thereof of the electromagnetic spectrum. In many embodiments, irradiating includes exposing to near-infrared radiation. In other embodiments, irradiating includes exposing to visible light. In other embodiments, irradiating includes exposing to any radiation on the electromagnetic spectrum. Converting generally refers to any process for converting energy.

The following Examples are intended to illustrate the above invention and should not be construed as to narrow its scope. One skilled in the art will readily recognize that the Examiners suggest many other ways in which the invention could be practiced. It should be understand that numerous variations and modifications may be made while remaining within the scope of the invention.

### Example 1

### Radiative Heat-Blocking Materials

Conventional heat-blocking windows rely on films coated on to the glass in an attempt to block as much of the near-infrared portion of the spectrum (about 780-2500 nm) as possible. The two most commonly used methods commercially are based on pyrolytically coated glass (fluorine-doped tin oxide, FTO, coated) or use alternating thin layers of silver and insulator. These are referred to, industrially, as Low-E and Solar control glass and are widely manufactured and deployed commercially.

It has been discovered that an organic system with a greatly reduced proportion of electron donor (or “hole scavenger”) to electron acceptor when combined in a bulk heterojunction yielded photovoltaics with high visual transparency while maintaining high power-conversion efficiencies. In addition to the electricity-generating benefits of this diluted system, surprisingly it has been discovered that the system also prevents heat from passing through the coated layers in the form of infrared radiation. In particular, it has been found that the heat-blocking benefits of said diluted organic system sometimes outweigh the electricity-producing qualities given the high energy cost of air conditioning in hot climates.

For a photovoltaic device to be visibly transparent to human eyes, it generally should not absorb light in the ‘visible’ region of the electromagnetic spectrum (e.g., between 400-700 nm, with a peak in sensitivity around 550 nm). Thus, in order for such a transparent solar cell to remain efficient, it should absorb light outside of this visible range—either in the ultraviolet region, near-infrared, or infrared regions. The sun's spectral output is such that there is more energy to be harvested in the infrared regions compared to the ultraviolet region, hence the photovoltaic devices described herein are based on the diluted organic system targets this near-infrared range to generate electricity.

Near-infrared and infrared radiation is responsible for much of the radiative heating experienced when exposed to direct sunlight. The resulting effect was that the diluted organic systems described herein, while initially intended solely for use as a photovoltaic device for electricity generation, also efficiently absorb heat in the form of near-infrared radiation. In brief, instead of the sun's near-infrared radiation passing through windows and heating up the interior of a building, the organic layers described herein can harvest this radiation and use it to generate electricity; preventing the heating of buildings while producing electricity. This heat-blocking effect occurred regardless of whether or not the photovoltaic device was being used to generate electricity, or even if all the layers required for the photovoltaic device were present. The primary component of this heat blocking device was the diluted active layer, which absorbed near-infrared radiation while allowing visible light to pass through. However, other layers in the photovoltaic device (such as transparent conducting oxide, ETL, HTL and transparent conductor) also absorbed near-infrared and infrared light to differing degrees, thus contributing to the heat blocking effect. Even in the absence of these ancillary layers, the diluted active layer alone was enough to realize a significant reduction in heat transmission, even though a photovoltaic device would not be functional in such a configuration.

While some other photovoltaic devices based on organic materials (as well more conventional photovoltaics based on silicon, CdTe and others) may absorb infrared radiation, the unique advantage of the organic systems described herein was the fact that heat-blocking occurred while maintaining high visible transparency. Other conventional photovoltaics absorb light in this visible region, thus making them unsuitable for windows due to an unacceptable reduction in transparency.

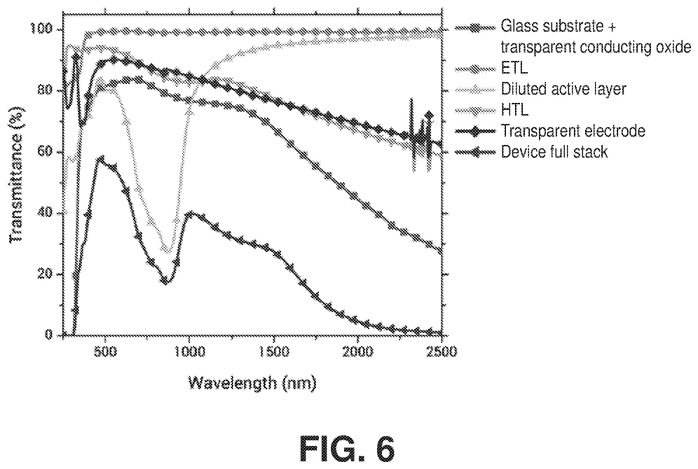

As shown in FIG. 6, all individual layers within the device displayed high AVTs>70%, with the hole-transport layer (HTL, a layer required for the photovoltaic device), transparent electrode (TE), and glass substrate+transparent conducting oxide (TCO) all showing much lower transmission beyond about 1000 nm. The diluted active layer showed a low transmission between about 700-1000 nm, with a minima at about 880 nm necessary for the conversion of near-infrared light into electricity. When fabricated into the layered structure with the configuration of Glass/TCO/ETL/AL (active layer)/HTL (hole-transport layer)/TE, referred to as ‘Device Full Stack’ in FIG. 6, it was shown that the transmission through the device can be considered as the subtraction of all the individual layers; showing low light transmission in in the region beyond about 700 nm (where light begins to be felt as heat) whilst maintaining a high AVT of about 50%. This high AVT combined with low infrared transparency was enabled through the diluted organic systems described herein: the visible light-absorbing hole scavenger was present in a low enough quantity so as not to reduce visible transparency, while the near-infrared-absorbing electron acceptor was allowed to harvest the beyond-visible photons and hence block them from passing through the window and causing a heating effect. In this figure, the full device stack was shown to be most effective at absorbing near-infrared and infrared light, however the diluted active layer was the largest single contributor to near-infrared light absorption as evidenced by the dip between about 700-900 nm.

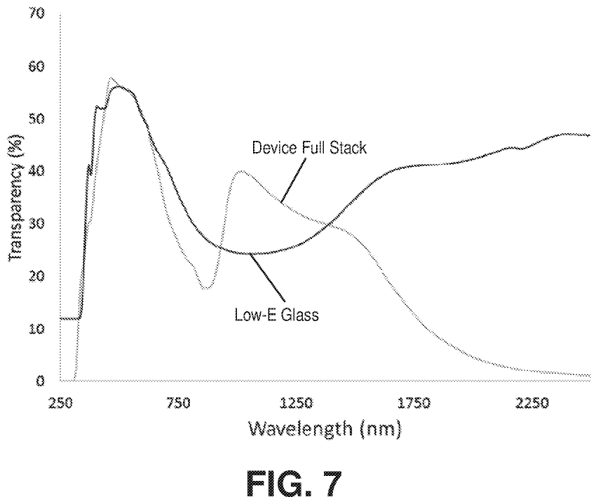

In comparison to a commercial Low-E glass with equivalent AVT, the ‘device full stack’ showed a lower transmission between about 780-950 nm and then again at about 1400 nm and beyond, as shown in FIG. 7.

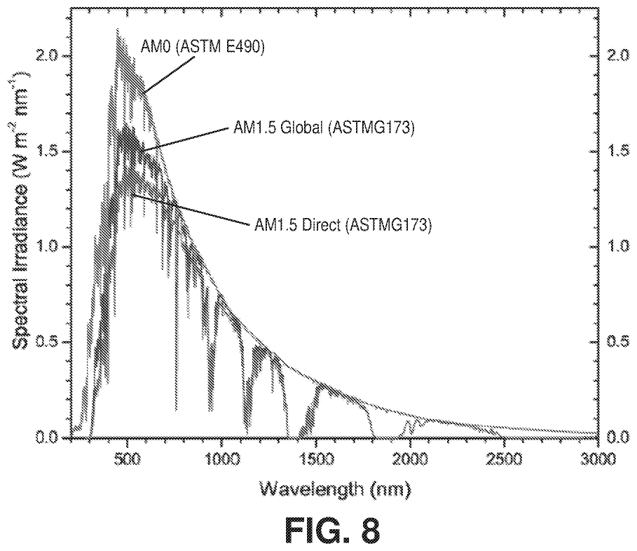

This transmission was important when put into the context of the different glass'/device's ability to transmit the available wavelengths emitted by the sun to earth's surface. Due to a combination of photophysical effects and atmospheric considerations the sunlight that reaches the earth's surface is not uniform at all wavelengths. The resulting spectrum is defined by the global average approximation standard known as ‘air-mass 1.5 global’ (AM1.5G), shown in FIG. 8. This shows the spectral irradiance in terms of watts per square meter for a given wavelength of light emitted from the sun reaching planet earth.

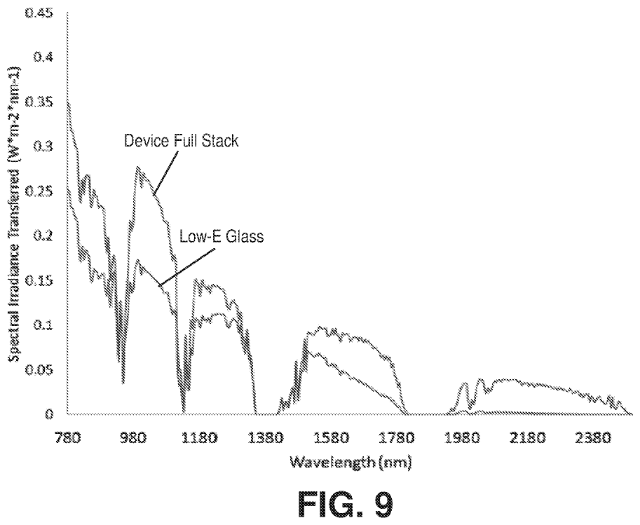

Taking into account the amount of sunlight attenuation through our films, FIG. 9 shows how much spectral irradiance would be transmitted through both the Low-E glass substrate and our ‘device full stack’ between about 780-2500 nm. By integrating the area under the respective traces, the relative differences in solar power (and hence, heat) transmitted through the different layers can be calculated. This revealed that the Low-E glass transmitted about 121 W/m² in this invisible light region, whereas the ‘device full stack’ transmitted only about 97 W/m², corresponding to about 30 and 25% energy transmission, respectively.

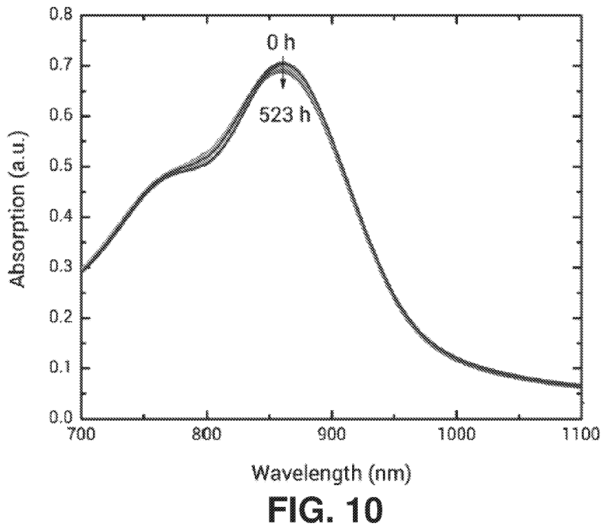

The heat blocking effect was the product of the light absorption in the near-infrared (and beyond) primarily of the active layer (diluted organic layer comprised of an electron donor/hole scavenger and acceptor material) as well as the transparent conducting oxide present on the electrode. The ETL and HTL layers played smaller roles in the heat blocking process, however their constituent materials may be switched. FIG. 10 is a graphical view showing absorption intensity of the diluted organic active layer over time while being subjected to continuous temperature stress (80 degrees centigrade) over the course of 523 hours, where a drop in peak absorption of 2.4% occurs over this time-frame, according to one or more embodiments of the present disclosure.

The long-term duration of this heat-blocking effect far exceeded the longevity of the photovoltaic device. While the photovoltaic based on the diluted organic system had an extrapolated lifetime of 10 years before reaching 80% of its original performance value, it was found that the degree of heat blocking deteriorated far slower over time under continuous temperature stress. It was extrapolated that, given such heating (80 degrees Celsius—greater than real-world conditions) for 1 hour per day in, for example, Saudi Arabia, the heat blocking effect would reach 80% of its original efficacy in 25 years. In a commercial product, this means that a window containing this diluted organic system could continue to provide benefit in terms of heat blocking for many years after the photovoltaic system has deteriorated in performance.

### Example 2

### Single-Component and Diluted Organic Systems

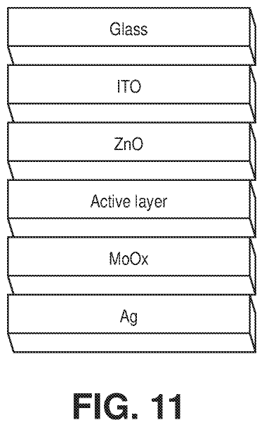

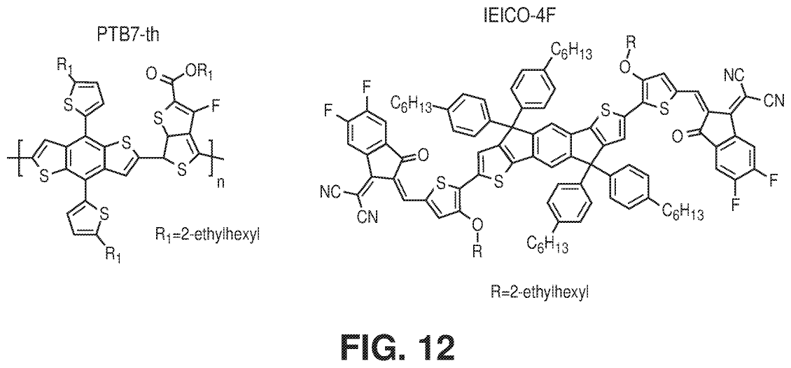

The Example described herein relates to novel single component and diluted systems. In particular, due to the different photophysical characteristics of NF compared to PC₇₀BM, a “diluted” system (D/A 1:10-1:25) was fabricated, which in combination with an infrared acceptor can feature AVT>70% and, at the same time, delivery PCE>5-6%. Ultra-fast (<300 fs) transient absorption spectroscopy (TAS) revealed that the non-fullerene acceptors featured intrinsic semiconductor properties, rather than excitonic. This is different from common donor and fullerene-based materials. In fact, the formation of free charges in the pristine non-fullerene acceptor material was observed in an ultra-short time scale, whereas the common state-of-the-art donors and acceptors depicted solely excitons. To prove the measurements, a single component organic solar cells (which could be alternatively named 0:1 diluted systems), based on IEICO-4F NF was fabricated in an inverted configuration based on ITO/ZnO/non-fullerene acceptor/MoOx/Ag (FIG. 11). FIG. 12 shows the current density versus voltage (J-V) characteristics of the single component device under AM1.5G illumination at 100 mWcm⁻². The solar cell delivered a short circuit current density (J_{sc}) of 3 mA cm⁻², an open-circuit voltage (V_{oc}) of 0.77 V, a fill factor of 32%, and an overall PCE of ˜1%. This result confirmed that the non-fullerene acceptors were able to efficiently split the excitons into free charges at room temperature without the need of a donor material and to collect holes and electrons in their respectively electrodes, due to the ambipolar nature of NFs. However, the limited PCE of the single component devices was attributed to the non-ohmic contact of the HOMO/LUMO level with the HTL and ETL, respectively and/or charge recombination processes in the material, due to defects and/or trap states formation.

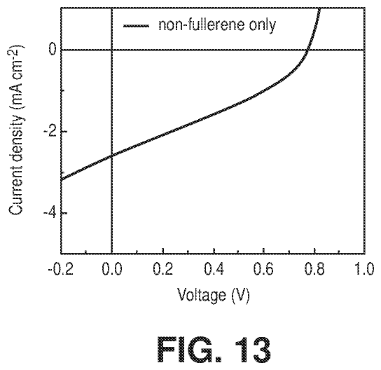

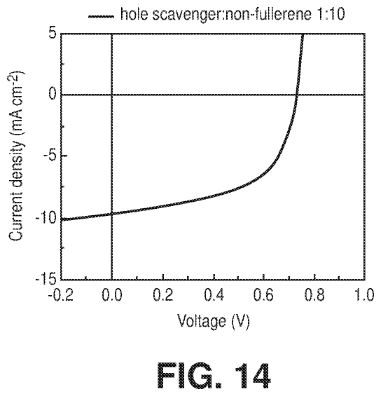

To reduce these limitations, a low amount of donor material (PTB7-th) was introduced to form diluted systems, in which the polymer/small molecule act as “hole scavenger” promoting the extraction of charges and therefore improving both FF and J_{sc} compared to the single component devices. FIG. 13 shows the current density versus voltage (J-V) characteristics the single component device under AM1.5G illumination at 100 mWcm⁻². The diluted system PTB7-Th:IEICO-4F devices delivered a PCE of 5% with 1:10 D/A. FIG. 14 is a graphical view of a diluted system comprising a ratio of hole-scavenging component to non-fullerene component of 1:10. Finally, a wide range of donor/NF systems were fabricated, making the approach of the present disclosure universal. In particular, this method provides an opportunity to reconsider all donor materials developed in the last 20 years for use in transparent organic opto-electronic devices.

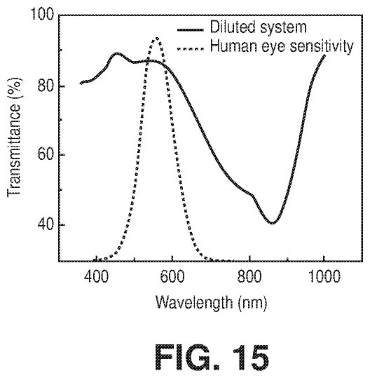

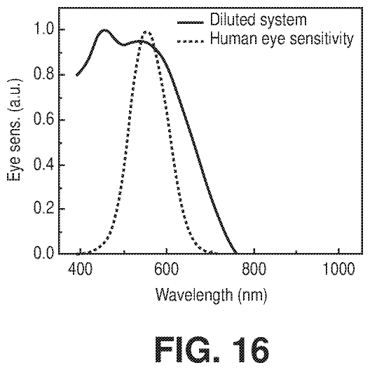

Interestingly, the AVT of the active layers of the diluted system based on PTB7-th:IEICO-4F were measured by UV/Vis spectroscopy. FIG. 15 shows the transmittance of the BHJ with respect the human eye sensitivity. An AVT of 70% was calculated for the all wavelength range (360-1000 nm), the highest reported so far for organic solar cells. Moreover, the transparency of the active layer was calculated according to the human eye response (FIG. 16). Transparency values as high as 90% were obtained for PTB7-th:IEICO-4F film. This is impressive, considering that the bare glass reduced the transparency up to 5-8%.

Photovoltaic modules represented an important test bed because real-world applications typically require large voltage outputs, which can be achieved through monolithic interconnection of consecutive cells. High solar module efficiencies were achieved on glass and on flexible substrates, importantly whilst maintaining a high AVT and GFF.

Fabrication and Characterization of OSCs. PTB7-Th was purchased from 1-Materials Inc. IEICO-4F was synthesized using conventional methods. PTB7-Th:IEICO-4F blend solution was prepared in chlorobenzene with a concentration of 20 mg/ml. The inverted device structure was ITO/zinc oxide (ZnO)/PTB7-Th:IEICO-4F/MoOx/Ag. ITO substrates were cleaned with detergent water, deionized water, acetone and isopropyl alcohol in an ultrasonic bath sequentially for 20 min Zinc oxide precursor solution was prepared by dissolving 2.4 g of zinc acetate dihydrate (Zn(CH₃COO)₂.2H₂O, 99%, Sigma) and 0.647 ml of ethanolamine (NH₂CH₂CH₂OH, 98%, Sigma) in 30 ml of 2-methoxyethanol (CH₃OCH₂CH₂OH, 98%, Sigma), then stirring the solution overnight. The ITO substrates were under UV-Ozone treatment for 30 min After the UV-Ozone treatment, ZnO precursor solution was spin coated at 4000 rpm onto the ITO substrates. After being baked at 200° C. for 10 min in air, the ZnO-coated substrates were transferred into nitrogen-filled glove box. The donor/acceptor blend solution was spin coated with different speed (300 rpm to 2000 rpm) to obtain different thickness. The device fabrication was completed by thermal evaporation of 5 nm MoOx (Alfa) and 100 nm Ag (Kurt Lesker) at a pressure of less than 2×10⁻⁶ Pa. The active area of all devices was 0.1 cm² through a shadow mask. J-V measurements of solar cells were performed in the glovebox with a Keithley 2400 source meter and an Oriel Sol3A Class AAA solar simulator calibrated to 1 sun, AM1.5 G, with a KG-5 silicon reference cell certified by Newport.

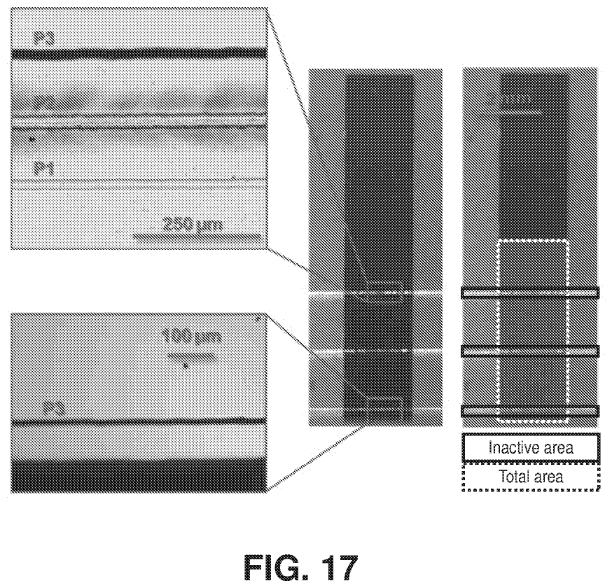

Module. The process involved high precision, ultrafast laser structuring of sequential, uniformly coated layers to form interconnects with low series resistance and reduced dead area. Glass/ITO and PET/ITO—Ag—ITO (IMI) substrates were used to realize both rigid and flexible devices, respectively. In order to achieve functional modules, three laser steps were necessary: the P1 laser defined the bottom electrode, the P2 line “opened” the photoactive layer to create a contact between top and bottom electrode and P3 electrically separated the top electrode (FIG. 17). The area between the P1 and the P3 line was not photoactive and thus can be considered a loss region (dead area).

This gives rise to the geometric fill factor (GFF), which is defined as

$$GFF = 100 ( 1 - \frac{DeadArea}{TotalArea} ) \% .$$

The closer the GFF to 100%, the lower the impact of the patterning technique on the final PCE of the solar module. The laser structuring made it possible to achieve interconnection regions of 250-300 μm and thus GFFs as high as 90%.

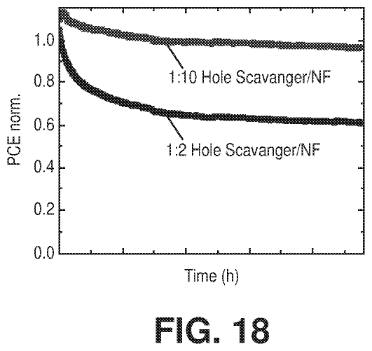

FIG. 18 is a graphical view of normalized PCE of 1:2 and 1:10 D/A based solar cells in the course of light exposure, according to one or more embodiments of the present disclosure. Upon device fabrication, the solar cells were placed in a sealed, electronically controlled degradation chamber with regulated environment (O₂<1 ppm, H₂O<1 ppm). The J-V characteristics of both 1:2 Hole Scavenger/NF and 1:10 Hole Scavenger/NF based devices were probed periodically while continuously light-soaked using a metal halide lamp irradiating at 100 mW/cm². As depicted in FIG. 18, the 1:10 Hole Scavenger/NF based solar cells show improved photostability compared to the 1:2 Hole Scavenger/NF based devices.

### Example 3

### Ternary Diluted Organic Systems

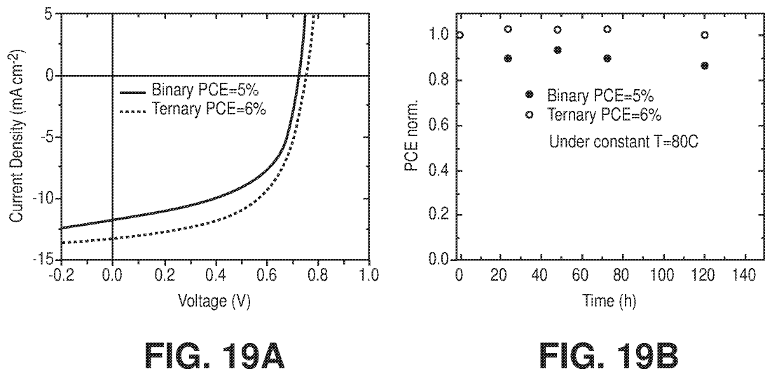

Organic ternary bulk heterojunction (BHJ) blends containing two electron donating and one electron accepting organic moieties (or vice versa) are among the most auspicious material systems deemed promising to overcome the important barrier of 15% power conversion efficiency (PCE) of organic photovoltaics (OPV). Using a third semiconducting absorber in the bulk heterojunction blend, the three key photovoltaic parameters, short-circuit current density (Jsc), open circuit voltage (Voc) and fill factor (FF) can, in principle, be manipulated and enhanced compared to devices based on binary blends. In this Example, an active layer based on a non-fullerene and two hole scavengers was used. With this approach a dual improvement of the power conversion efficiency and the thermal stability for the ternary blends was obtained when compared with the reference devices based on a non-fullerene and one hole scavenger. In fact, ternary devices delivered a PCE of 6%, whereas binary cells showed lower PCE of 5%. Moreover, temperature degradation measurements carried out in inert atmosphere at 80 degrees C. show improved stability for ternary blends compared to binary devices. The results are reported in FIGS. 19A-19B.

### Example 4

### Diluted Systems Coated on Commerically Available Glass

The common substrate used for organic solar cells consists of a glass coated with Indium Tin Oxide (ITO) characterized by low sheet resistance (<15 Ohm/sq) and low roughness (<1 nm). The low roughness allows the fabrication of organic solar cells without any defects and/or pin holes, which would have a detrimental effect on the performances. For commercial valuable product, ITO has to be replaced by Fluorine doped Tin Oxide (FTO), for costing perspective. However, conventional organic solar cells feature low efficiency when fabricated on FTO for the higher roughness of the substrate compared to ITO. In this Example, organic solar cells based on non-fullerene and one or more hole scavengers were fabricated on commercially available FTO. The devices delivered comparable PCE with the standard ITO-based solar cells. The short-circuit current density was the only parameter affected by the substrate replacement, due to the higher parasitic absorption in the NIR of FTO compared to ITO. It was found that the diluted systems featured a higher tolerance toward defect/roughness of the substrate compare to convention donor:acceptor blends. The results are reported in Table 1.

TABLE 1
Photovoltaic parameters of hole scavenger:NF
(1:10) based devices at 1 sun illumination on
different glass/FTO and glass/ITO substrates.

| | Jsc | Voc | Fill | PCE | | RMS |
|---|---|---|---|---|---|---|
| | (mA/cm2) | (V) | Factor | (%) | Ohms/sq | (nm) |
| Commercial | 10.1 | 0.70 | 0.59 | 4.18 | 30.000 | 5.000 |
| FTO-1 | | | | | | |
| Commercial | 9.8 | 0.71 | 0.56 | 3.89 | 15.000 | 8.000 |
| FTO-2 | | | | | | |
| Commercial | 8.5 | 0.71 | 0.59 | 3.56 | 10.000 | 10.000 |
| FTO-3 | | | | | | |
| Commercial | 10.2 | 0.68 | 0.40 | 2.77 | 15.000 | 17.000 |
| FTO-4 | | | | | | |
| Commercial | 12.3 | 0.72 | 0.58 | 5.13 | 8.0 | 12.0 |
| FTO-5 | | | | | | |
| ITO | 12.5 | 0.73 | 0.60 | 5.48 | 10.0 | 3.0 |

### Example 5

### Hybrid Tandem Solar Cells

Typical solar cells are based on a single layer of photovoltaic material, whether it be based on silicon, perovskite, or an organic bulk heterojunction. However, there are fundamental physical limits to how efficient this single layer is at converting light into electricity: In the best case, this efficiency ceiling is around 33%. However, as described herein, by ‘stacking’ multiple photovoltaic materials on top of one another in the same device (known as ‘multi-junction’ or ‘tandem’ solar cells), light was harvested more efficiently, and the 33% efficiency limit was raised Importantly, it was necessary for the short-circuit current density (JSC) of both sub-cells to be as similar as possible in order to realize efficient tandem solar cells (The JSC of the tandem device is limited to the lowest sub-cell's JSC, while the open-circuit voltages, VOCs, of the sub-cells are summed).

Accordingly, a process of fabricating the diluted organic systems described herein using another solar cell as a substrate was developed. This ‘front cell’ was based on a layer of amorphous silicon (a-Si) which absorbs some light in the visible region of the solar spectrum (while allowing some visible light to pass, retaining some transparency), whilst allowing the invisible (near infrared) wavelengths to pass through freely and be absorbed by the diluted organic ‘back cell’ as described herein. Such tandem solar cells can greatly improve the efficiency of a-Si solar cells with no significant disadvantages compared to pristine a-Si alone. The diluted organic photovoltaic materials described herein exhibited nearly identical JSC compared to standard a-Si solar cell while maintaining high visible transparency. This meant the new tandem device exhibited a much higher VOC (and hence, efficiency) with no appreciable decrease in the visual transparency or JSC limitations.

This device structure is envisaged to be used in commercial applications where a slightly ‘darker’ solar panel is required, wherein the optical properties can still be tuned by varying the donor and acceptor ratios as described in the present disclosure.

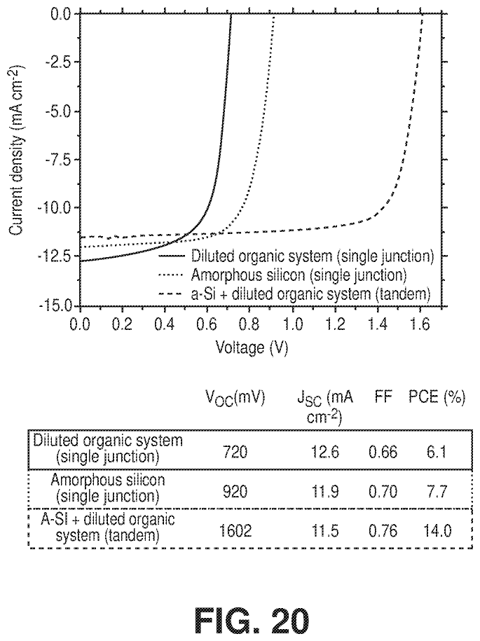

FIG. 20 shows the current-voltage responses of single-junction organic (blue), single-junction a-Si (red) and multi-junction tandem solar cells (orange). The underlying table shows that by utilizing this tandem structure, the power conversion efficiency of an a-Si solar cell was improved from 7.7% to 14.0%.

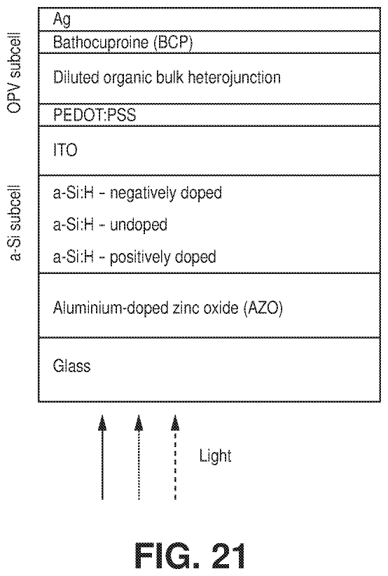

FIG. 21 is a schematic drawing of a tandem solar cell, according to one or more embodiments of the present disclosure.

Other embodiments of the present disclosure are possible. Although the description above contains much specificity, these should not be construed as limiting the scope of the disclosure, but as merely providing illustrations of some of the presently preferred embodiments of this disclosure. It is also contemplated that various combinations or sub-combinations of the specific features and aspects of the embodiments may be made and still fall within the scope of this disclosure. It should be understood that various features and aspects of the disclosed embodiments can be combined with or substituted for one another in order to form various embodiments. Thus, it is intended that the scope of at least some of the present disclosure should not be limited by the particular disclosed embodiments described above.

Thus the scope of this disclosure should be determined by the appended claims and their legal equivalents. Therefore, it will be appreciated that the scope of the present disclosure fully encompasses other embodiments which may become obvious to those skilled in the art, and that the scope of the present disclosure is accordingly to be limited by nothing other than the appended claims, in which reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present disclosure, for it to be encompassed by the present claims. Furthermore, no element, component, or method step in the present disclosure is intended to be dedicated to the public regardless of whether the element, component, or method step is explicitly recited in the claims.

The foregoing description of various preferred embodiments of the disclosure have been presented for purposes of illustration and description. It is not intended to be exhaustive or to limit the disclosure to the precise embodiments, and obviously many modifications and variations are possible in light of the above teaching. The example embodiments, as described above, were chosen and described in order to best explain the principles of the disclosure and its practical application to thereby enable others skilled in the art to best utilize the disclosure in various embodiments and with various modifications as are suited to the particular use contemplated. It is intended that the scope of the disclosure be defined by the claims appended hereto

Various examples have been described. These and other examples are within the scope of the following claims.

What is claimed is:

1. A window, comprising:
a transparent photovoltaic device configured to transmit visible light and absorb infrared radiation, wherein an active layer of the photovoltaic device comprises a radiative heat-blocking material, the radiative heat-blocking material comprising one or more non-fullerene components and optionally one or more hole-scavenging components.

2. The window according to claim 1, wherein the photovoltaic device is configured to maintain an average visible transmittance of at least about 50%.

3. The window according to any one of claims 1-2, wherein the photovoltaic device is configured with a power conversion efficiency of at least about 5%.

4. The window according to any one of claims 1-3, wherein the transmitted visible light has a wavelength in the range of about 380 nm to about 700 nm, or any value or incremental range between about 380 nm and about 700 nm.

5. The window according to any one of claims 1-4, wherein the absorbed infrared radiation has a wavelength in the range of about 700 nm to about 3000 nm, or any value or incremental range between about 700 nm and about 3000 nm.

6. The window according to any one of claims 1-5, wherein the one or more hole-scavenging components comprise a first hole-scavenging component and a second hole-scavenging component that is different form the first hole-scavenging component.

7. The material according to any one of claims 1-6, wherein a ratio of the one or more hole-scavenging component to the one or more non-fullerene components ranges from about 1:10 to about 1:25.

8. The window according to any one of claims 1-7, wherein the one or more hole scavenging components are selected from thiophene, acene, fluorine, carbazole, indacenodithieno thiophene, indacenothieno thiphene, benzodithiazole, thieny-benzodithiophene-dione, benzotriazole, diketopyrrolopyrrole, and combinations thereof.

9. The window according to any one of claims 1-8, wherein the one or more non-fullerene components is selected from rhodanine-benzothiadiazole-coupled indacenodithiophene (IDTBR); indacenodithieno[3,2-b]thiophene, IT), end-capped with 2-(3-oxo-2,3-dihydroinden-1-ylidene)malononitrile (INCN) groups (ITIC); indaceno[1,2-b:5,6-b′]dithiophene and 2-(3-oxo-2,3-dihydroinden-1-ylidene)malononitrile (IEIC); 2,2′-((2Z,2′Z)-((5,5′-(4,4,9,9-tetrakis(4-hexylphenyl)-4,9-dihydro-s-indaceno[1,2-b:5,6-b′]dithiophene-2,7-diyl)bis(4-((2-ethylhexyl)-oxy)thiophene-5,2-diyl))bis(methanylylidene))bis(3-oxo-2,3-di-hydro-1H-indene-2,1-diylidene))dimalononitrile (IEICO); naphthalene diimide (NDI); bay-linked perylene bisimide (di-PBI); perylene bisimide (PBI); Benzotriazole-Containing End-Capped with Thiazolidine-2,4-dione (TD); Naphthalocyanine (NC); Phthalocyanine (PC); Naphtho[1,2-c:5,6-c′]bis[1,2,5]thiadiazole; (2E,2′E)-3,3′-(2,5-dimethoxy-1,4-phenylene)bis(2-(5-(4-(N-(2-ethylhexyl)-1,8-naphthalimide)yl)thiophen-2-yl)acrylonitrile) (NIDCS-MO); thieno[3,4-b] thiophene and 2-(1,1-dicyanomethylene)rhodanine combination (ATT-1); (3,9-bis(4-(1,1-dicyanomethylene)-3-methylene-2-oxo-cyclopenta[b]thiophen)-5,5,11,11-tetrakis(4-hexylphenyl)-dithieno[2,3-d′:2,3-d′]-s-indaceno[1,2-b: 5,6-b′]-dithiophene (ITCC); Indanedione; Dicyannovinyl; Benzothiadiazole; Diketopyrolopyrrole; arylene diimide; IDIC; and combinations thereof.

10. The window according to any one of claims 1-9, wherein the photovoltaic device further comprises:
a first electrode material and a second electrode material disposed on opposing sides of the radiative heat-blocking material.

11. The window according to claim 10, wherein the photovoltaic device further comprises:
a first selective contact layer disposed between the radiative heat-blocking material and the first electrode material;
a second selective contact layer disposed between the radiative heat-blocking material and the second electrode material; and
a substrate in contact with either the first electrode material or the second electrode material and otherwise exposed to an environment.

12. A radiative heat-blocking material, comprising:
one or more non-fullerene components; and
one or more hole-scavenging components;
wherein the heat-blocking material transmits visible light and absorbs infrared radiation.

13. The material according to claim 12, wherein the photovoltaic device is configured to maintain an average visible transmittance of at least about 50%.

14. The material according to any one of claims 1-13, wherein the transmitted visible light has a wavelength in the range of about 380 nm to about 700 nm, or any value or incremental range between about 380 nm and about 700 nm.

15. The material according to any one of claims 1-14, wherein the absorbed infrared radiation has a wavelength in the range of about 700 nm to about 3000 nm, or any value or incremental range between about 700 nm and about 3000 nm.

16. The material according to any one of claims 1-15, wherein the one or more hole-scavenging components comprise a first hole-scavenging component and a second hole-scavenging component that is different form the first hole-scavenging component.

17. The material according to any one of claims 1-16, wherein a ratio of the one or more hole-scavenging component to the one or more non-fullerene components ranges from about 1:10 to about 1:25.

18. The material according to any one of claims 1-17, wherein the one or more hole scavenging components are selected from thiophene, acene, fluorine, carbazole, indacenodithieno thiophene, indacenothieno thiphene, benzodithiazole, thieny-benzodithiophene-dione, benzotriazole, diketopyrrolopyrrole, and combinations thereof.

19. The material according to any one of claims 1-18, wherein the one or more non-fullerene components is selected from rhodanine-benzothiadiazole-coupled indacenodithiophene (IDTBR); indacenodithieno[3,2-b]thiophene, IT), end-capped with 2-(3-oxo-2,3-dihydroinden-1-ylidene)malononitrile (INCN) groups (ITIC); indaceno[1,2-b:5,6-b′]dithiophene and 2-(3-oxo-2,3-dihydroinden-1-ylidene)malononitrile (IEIC); 2,2′-((2Z,2′Z)-((5,5′-(4,4,9,9-tetrakis(4-hexylphenyl)-4,9-dihydro-s-indaceno[1,2-b:5,6-b′]dithiophene-2,7-diyl)bis(4-((2-ethylhexyl)-oxy)thiophene-5,2-diyl))bis(methanylylidene))bis(3-oxo-2,3-di-hydro-1H-indene-2,1-diylidene))dimalononitrile (IEICO); naphthalene diimide (NDI); bay-linked perylene bisimide (di-PBI); perylene bisimide (PBI); Benzotriazole-Containing End-Capped with Thiazolidine-2,4-dione (TD); Naphthalocyanine (NC); Phthalocyanine (PC); Naphtho[1,2-c:5,6-c′]bis[1,2,5]thiadiazole; (2E,2′E)-3,3′-(2,5-dimethoxy-1,4-phenylene)bis(2-(5-(4-(N-(2-ethylhexyl)-1,8-naphthalimide)yl)thiophen-2-yl)acrylonitrile) (NIDCS-MO); thieno[3,4-b] thiophene and 2-(1,1-dicyanomethylene)rhodanine combination (ATT-1); (3,9-bis(4-(1,1-dicyanomethylene)-3-methylene-2-oxo-cyclopenta[b]thiophen)-5,5,11,11-tetrakis(4-hexylphenyl)-dithieno[2,3-d′:2,3-d′]-s-indaceno[1,2-b: 5,6-b′]-dithiophene (ITCC); Indanedione; Dicyannovinyl; Benzothiadiazole; Diketopyrolopyrrole; arylene diimide; IDIC; and combinations thereof.

20. A window comprising the radiative heat-blocking material of claims 12-19 deposited on a surface thereof.
